(19) United States
(12) Patent Application Publication
(10) Pub. No.: US 2009/0130326 A1
(43) Pub. Date: May 21, 2009

(54) FILM FORMING MATERIAL AND METHOD OF FILM FORMING

(75) Inventors: Hideaki Machida, Yamanashi (JP); Ikuyo Muramoto, Yamanashi (JP); Young Hua Xu, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TRI CHEMICAL LABORATORIES INC., UENOHARA-SHI YAMANASHI (JP)

(21) Appl. No.: 11/813,622

(22) PCT Filed: Jan. 10, 2006
(86) PCT No.: PCT/JP2006/300150

§ 371 Date: Jan. 15, 2009

(30) Foreign Application Priority Data
Jan. 20, 2005 (JP) 2005005676

(51) Int. Cl. C23C 4/04; C07F 7/08; B05D 3/02; C23C 16/00

(52) U.S. Cl. 427/452; 556/487; 427/255.6; 427/553

(57) ABSTRACT

An interlayer insulating film enabling an enhancement in a signal processing speed to be obtained, of which a dielectric constant is 2.2 or less. There is provided a method of forming a film on a substrate in accordance with a chemical vapor deposition process, comprising: the feeding step of feeding (c-C₅H₉)₂Si(OCH₃)₂ by inert gas bubbling; and the deposition step of causing any of decomposition product resulting from decomposition of the (c-C₅H₉)₂Si(OCH₃)₂ fed in the above feeding step to deposit on the substrate.

### APPLICABLE FIELD IN THE INDUSTRY

The present invention relates to, for example, a material for forming an interlayer insulating film of a semiconductor element, a method of employing the above material to form the interlayer insulating film in accordance with a chemical vapor deposition process, and moreover, a semiconductor element.

### BACKGROUND ART

At present, a progress in a semiconductor field is remarkable, and the semiconductor has shifted to a ULSI from an LSI. And, for a purpose of enhancing a processing speed of a signal, and further from the other requests, micronization of the semiconductor has progressed. Accompanied by this, a wiring width is narrowed, and the line of the wiring becomes ultra-fine. From such a reason, it is said that the conventional tungsten (W) wiring film, and moreover, aluminum (Al) wiring film are not capable of enduring the fine-line processing. And, it has been proposed to employ copper (Cu) as a material of the wiring film.

However, it begins to be said that copper (Cu) having low electrical resistance is still insufficient for the wiring film material even though it is employed as a wiring film material.

That is, enhancing a processing speed of the signal has necessitated an improvement as well to an insulating film between the wiring films. For example, conventionally, the interlayer insulating film between the wiring films was configured of SiO₂. However, from a viewpoint of enhancing a processing speed of the signal, recently, employment of the material of which a dielectric constant is lower than that of SiO₂ for the interlayer insulating film has begun to be proposed. That is, it is said that employing the material of which the dielectric constant is lower than that of SiO₂ as a material of the interlayer insulating film alleviates a delay of a signal.

Patent document 1: WO99/57330 (JP-P2002-514004A)

Patent document 2: JP-P2000-216153A

Patent document 3: JP-P2003-151972A

### DISCLOSURE OF THE INVENTION

### Problems to be Solved by the Invention

So far, from a viewpoint of enhancing a signal speed, the low-resistance metal has been proposed as a wiring film material, and further, the SiO₂ material of which the dielectric constant is low as an interlayer insulating film material, respectively.

And, as a technology of forming the interlayer insulating film of which the dielectric constant is low, as proposed by the above-mentioned patent documents, the scheme of employing a silicon alkoxide of RnSi(OR)m to form a film with the chemical vapor deposition process (CVD) was tried. And, the result was obtained correspondingly.

However, it cannot be said that even with the material proposed so far, the dielectric constant thereof is sufficiently low, which demands moreover development.

Further, in a damascene wiring structure of a copper (Cu)/low-dielectric constant insulating film wiring, various kinds of the processes such as etching, ashing, cleaning, and moreover, CMP (chemical mechanical polishing) are performed for the insulating film. Thus, the high mechanical strength is requested of the insulating film so as to make the insulating film more resistive to damage in performing these processes.

And, the conventional insulating film is not a satisfactory one from a viewpoint of such a characteristic in terms of the strength.

Thus, a first problem to be solved by the present invention is solved by providing a material with a small dielectric constant preferred as an interlayer insulating film that enables an enhancement in the processing speed of the signal to be obtained.

A second problem to be solved by the present invention is solved by providing a material that enables the film with the mechanical strength endurable against the CMP to be formed.

### Means to Solve the Problem

This inventor has come to notice that the dielectric constant or the film strength of the insulating film being formed is governed considerably due to a structural difference of a raw material compound being employed even though a silicon alkylalkoxide of RnSi(OR)m is employed to form a film with the CVD, in the course of earnestly moving ahead with a research for solving the foregoing problem.

And, the inventor has vigorously moved ahead with an investigation on various types of the silicon alkylalkoxides based upon such knowledge.

As a result, the inventor has reached the fact that the film formed from dicyclopentyldimethoxysilane [(c-C₅H₉)₂Si(OCH₃)₂], being a raw material, is very promising as an interlayer insulating film.

The present invention has been accomplished based upon such knowledge.

That is, the foregoing problem is solved by the film forming material, which is a material for forming a film with the chemical vapor deposition process, and is characterized in including (c-C₅H₉)₂Si(OCH₃)₂.

For example, the foregoing problem is solved by the film forming material, which is a material for forming a film with the chemical vapor deposition process, and is characterized in consisting of (c-C₅H₉)₂Si(OCH₃)₂.

In particular, the foregoing problem is solved by the film forming material, which is a material for forming a insulating film of which the dielectric constant is 2.2 or less with the chemical vapor deposition process, and is characterized in including (c-C₅H₉)₂Si(OCH₃)₂.

For example, the foregoing problem is solved by the film forming material, which is a material for forming a insulating film of which the dielectric constant is 2.2 or less with the chemical vapor deposition process, and is characterized in consisting of (c-C₅H₉)₂Si(OCH₃)₂.

Employing the above-mentioned film forming material allows a Si—O—C film to be formed. And, the dielectric constant of this film is small. In particular, it is 2.1 or less, and it is small in such a manner of being, for example, 1.9 to 2.1. Thus, the formed film is very desirable as an interlayer insulating film in the semiconductor element. Yet, it is a film of which the elastic modulus is 5 GPa or more. Thus, there is no possibility that the accident of the film being exfoliated in the CMP occurs. That is, the very small restrictions are put on the CMP in forming the wiring film.

Additionally, the invention of claim 3 relates to the inventions of claim 1 and claim 2. The invention of claim 4 relates to the inventions of claim 1, claim 2, and claim 3.

Further, the foregoing problem is solved by the film forming method, which is a method of forming a film on a substrate with the chemical vapor deposition process, and is characterized in including:

a feeding step of feeding (c-C₅H₉)₂Si(OCH₃)₂; and

a deposition step of causing any decomposition product resulting from decomposition of the (c-C₅H₉)₂Si(OCH₃)₂ fed in the feeding step to deposit on the substrate.

In particular, the foregoing problem is solved by the film forming method, which is a method of forming a film on a substrate with the chemical vapor deposition process, and is characterized in including:

a feeding step of feeding (c-C₅H₉)₂Si(OCH₃)₂ by bubbling of inert gas; and
a deposition step of causing any decomposition product resulting from decomposition of the (C—C₅H₉)₂Si(OCH₃)₂ fed in the feeding step to deposit on the substrate.

In addition hereto, the foregoing problem is solved by the film forming method, which is a method of forming a film on a substrate with the chemical vapor deposition process, and is characterized in including:

a feeding step of feeding (c-C₅H₉)₂Si(OCH₃)₂ by bubbling of inert gas of which a flow amount is 10 to 500 sccm (particularly, 50 sccm or more. 200 sccm or less); and

a deposition step of causing any decomposition product resulting from decomposition of the (c-C₅H₉)₂Si(OCH₃)₂ fed in the feeding step to deposit on the substrate.

In the above-mentioned film forming method, with a feed ratio (pressure ratio) of the (c-C₅H₉)₂Si(OCH₃)₂ and the inert gas, the former/the latter is desirably 1/10 to ½ (above all, ⅕ or more. ⅓ or less). A total feeding amount (a total pressure in a decomposition chamber) of the (c-C₅H₉)₂Si(OCH₃)₂ and the inert gas is desirably 0.1 to 10 Torr (particularly, 1 Torr or more. 5 Torr or less).

Various techniques about the decomposition/deposition of the raw material compound in the CVD are known so far. Also in the present invention, the conventional techniques can be employed. The decomposition/deposition of the (c-C₅H₉)₂Si(OCH₃)₂ is carried out desirably by using both of a plasma means and a heating means even though its reason, however, has not been elucidated fully theoretically yet. The reason is that the film obtained in such a manner was most desirable as an interlayer insulating film.

Further, the plasma means including parallel plate electrodes of which an inter-electrode distance was 20 to 250 mm (particularly, 50 mm or more. 120 mm or less) was employed desirably in forming the Si—O—C—H interlayer insulating film with the plasma CVD. In particular, the plasma means in which one electrode of the parallel plate electrodes acted as a substrate stage as well, and the other electrode acted as a blowing shower of the (c-C₅H₉)₂Si(OCH₃)₂ as well was employed desirably. Further, the plasma of which a power was 10 to 400 W was employed desirably.

Further, it is desirable to keep the substrate on which the decomposition product deposits at 200 to 500° C. (particularly, 300° C. or more. 450° C. or less).

By the way, the film (the insulating film; low dielectric constant film) formed in such a manner does not have to be post-treated. That is, the dielectric constant of the obtained film is small, and the film strength thereof is high.

However, it is desirable to radiate an electromagnetic wave (for example, light such as ultra violent rays) to the formed film in some cases, and to perform a heat-treatment for it, for example, to heat it in some cases. For example, it is one of desirable things to radiate the ultra violent rays of which the output power is 1 to 10 mW/cm² for 0.1 to 130 sec (desirably, 30 sec or more. 90 sec or less). It is also one of desirable things to heat the film at 300 to 500° C. for one sec to one hour (desirably, 60 sec or more. 40 minutes or less). That is, by performing the post-treatment as mentioned above, the dielectric constant became small all the more.

Additionally, the invention of claim 8 relates to the inventions of claim 6 and claim 7. The invention of claim 9 relates to the inventions of claim 6, claim 7, and claim 8. The invention of claim 10 relates to the inventions of claim 5, claim 6, claim 7, claim 8, and claim 9. The invention of claim 11 relates to the inventions of claim 5, claim 6, claim 7, claim 8, claim 9, and claim 10. The invention of claim 12 relates to the inventions of claim 5, claim 6, claim 7, claim 8, claim 9, claim 10, and claim 11. The invention of claim 13 relates to the inventions of claim 5, claim 6, claim 7, claim 8, claim 9, claim 10, claim 11, and claim 12. The invention of claim 14 relates to the inventions of claim 5, claim 6, claim 7, claim 8, claim 9, claim 10, claim 11, claim 12, and claim 13.

### EFFECTS OF THE INVENTION

The present invention employed the (c-C₅H₉)₂Si(OCH₃)₂, for example, as a raw material for forming the interlayer insulating film of the semiconductor element, and in particular, as a raw material for forming the interlayer insulating film with the CVD. Thus, the Si—O—C—H insulating film of which the dielectric constant was small was easily formed. In particular, the insulating film with the film strength of which the elastic modulus was 5 GPa or more was formed. And, an enhancement in the signal processing speed is expected in the case of configure the above film as an interlayer insulating film in the semiconductor element. In addition hereto, the damage to the film by the CMP hardly occur, and a production yield of the semiconductor element is improved.

Further, in forming the Si—O—C—H film with the CVD employing the (c-C₅H₉)₂Si(OCH₃)₂, when the (c-C₅H₉)₂Si(OCH₃)₂ is fed by bubbling of the inert gas of which a flow amount is 10 to 500 sccm (particularly, 50 sccm or more. 200 sccm or less), the Si—O—C—H insulating film of which the dielectric constant is small can be formed finely.

In the present invention, the reason why it has been judged that with a feed ratio (pressure ratio) of the (c-C₅H₉)₂Si(OCH₃)₂ and the inert gas, the former/the latter is desirably 1/10 to ½ (above all, ⅕ or more. ⅓ or less) is described as follows. That is, the reason is that in a case where the former/the latter was less than 1/10, and contrarily, in a case where it was larger than ½, it was difficult to form the Si—O—C—H insulating film of which the dielectric constant was small.

Further, the reason why it has been judged that a total feed amount (a total pressure in a decomposition chamber) of the (c-C₅H₉)₂Si(OCH₃)₂ and the inert gas is desirably 0.1 to 10 Torr (particularly, 1 Torr or more. 5 Torr or less) is described as follows. That is, the reason is that in a case where it was less than 0.1 Torr, it was difficult to form the Si—O—C—H insulating film of which the dielectric constant was small, and contrarily, in a case where it was more than 10 Torr, it was difficult for the plasma to start, and the compound was not decomposed efficiently.

It is well known that in the film forming by the CVD, various techniques such as light, laser, plasma, and heat are employed for decomposing the raw material compound. Also in the present invention, any of the foregoing techniques can be employed. However, the present invention employing the (c-C₅H₉)₂Si(OCH₃)₂ as a raw material compound showed a most desirable result in the case of using both of the plasma means and the heating means. That is, the film fabricated through the course of the decomposition/deposition by the plasma means and the heating means exhibited a more excellent performance as an interlayer insulating film in the semiconductor element than the film fabricated through the course of the decomposition/deposition only by the plasma means, or only the heating means.

It was most desirable to employ the parallel plate electrodes of which the inter-electrode distance was 20 to 250 mm (particularly, 50 mm or more. 120 mm or less) in the plasma CVD of the present invention. In particular, the type of the plasma CVD was desirable in which one electrode of the parallel plate electrodes acted as a substrate stage as well, and the other electrode acted as a blowing shower of the (c-C₅H₉)₂Si(OCH₃)₂ as well. That is, in a case of employing the CVD of such a type, and decomposing the (c-C₅H₉)₂Si(OCH₃)₂/causing it to deposit, the film forming, which kept an intra-plane uniformity of the substrate and was excellent in reproduction, was possible in forming the Si—O—C—H film.

Further, the output of the plasma was desirably 10 to 400 W. The reason is that in a case where the output was too large, organic C—C₅H₉ hardly remained in the film, and in a case where the output was too small, the decomposition of the (c-C₅H₉)₂Si(OCH₃)₂ did not progress well, and it was difficult to form the film of which the dielectric constant was small.

Further, when, after forming a film, the above film was post-treated, for example, the electromagnetic wave (light) was radiated hereto, or it was heat-treated, the dielectric constant became smaller all the more. Thus, it was very desirable to perform such a process.

### BRIEF DESCRIPTION OF THE DRAWINGS

FIG. 1 is a schematic view of the film forming device (CVD).

### DESCRIPTION OF NUMERALS

1 raw material container
2 electrode acting as a heater and for plasma discharging
3 decomposition reactor
4 Si substrate
5 gas flow amount controller
6 electrode acting as a gas blowing shower head and for plasma discharging
7 inert gas feeding path

### BEST MODE FOR CARRYING OUT THE INVENTION

The film forming material in accordance with the present invention is a film forming material for forming the film with the CVD. In particular, it is a material for forming the insulating film of which the dielectric constant is 2.2 or less (particularly, 2.1 or less. For example, 1.9 to 2.1). Further, it is a material for forming the insulating film with the film strength of which the elastic modulus is 5 GPa or more (No special restrain to the upper limit value exist; however practically, for example, 8.3 GPa or so). In addition hereto, it is a material for forming the Si—O—C—H film. Above all, it is a material for forming the interlayer insulating film in the semiconductor element. This material (raw material) is (C—C₅H₉)₂Si(OCH₃)₂.

The film forming method in accordance with the present invention is a method of forming the above-mentioned film.

That is, it is a method of forming the film by employing the (c-C₅H₉)₂Si(OCH₃)₂ and yet with the CVD for a purpose of forming the above-mentioned film. For example, It is a method of forming the film on the substrate with the chemical vapor deposition process, which includes: a feeding step of feeding (c-C₅H₉)₂Si(OCH₃)₂; and a deposition step of causing any decomposition product resulting from decomposition of the (C—C₅H₉)₂Si(OCH₃)₂ fed in the feeding step to deposit on the substrate. In particular, it includes: a feeding step of feeding the (c-C₅H₉)₂Si(OCH₃)₂ by bubbling of the inert gas; and a deposition step of causing any decomposition product resulting from decomposition of the (c-C₅H₉)₂Si(OCH₃)₂ fed in the feeding step to deposit on the substrate. In addition hereto, it includes: a feeding step of feeding the (c-C₅H₉)₂Si(OCH₃)₂ by bubbling of the inert gas of which a flow amount is 10 to 500 sccm (particularly, 50 sccm or more. 200 sccm or less); and a deposition step of causing any decomposition product resulting from decomposition of the (c-C₅H₉)₂Si(OCH₃)₂ fed in the feeding step to deposit on the substrate. And, desirably, after forming a film (deposition step), the above film is post-treated, for example, the electromagnetic wave (light) is radiated hereto in some cases, and it is heat-treated in some cases.

With a feed ratio (pressure ratio) of the above-mentioned (c-C₅H₉)₂Si(OCH₃)₂ and inert gas, the former/the latter is particularly 1/10 to ½ (above all, ⅕ or more. ⅓ or less). Further, a total feed amount (a total pressure in a decomposition chamber) of the (c-C₅H₉)₂Si(OCH₃)₂ and the inert gas is particularly 0.1 to 10 Torr (particularly, 1 Torr or more. 5 Torr or less). For the decomposition/deposition of the raw material compound in the CVD, particularly, both of the plasma means and the heating means are used. The plasma CVD including the parallel plate electrodes of which the inter-electrode distance is 20 to 250 mm (particularly, 50 mm or more. 120 mm or less) is particularly employed for a plasma CVD. Above all, the plasma CVD is employed in which one electrode of the parallel plate electrodes acts as a substrate stage as well, and the other electrode acts as a blowing shower of the (c-C₅H₉)₂Si(OCH₃)₂ as well.

After the above-mentioned process, for example, the ultra violent rays of which the output power is 1 to 10 mW/cm² for 0.1 to 130 sec (desirably, 30 sec or more. 90 sec or less) is radiated. Or, the film is heated at 300 to 500° C. for one sec to one hour (desirably, 60 sec or more. 40 minutes or less).

Hereinafter, specific examples will be listed for explanation.

### EXAMPLE 1

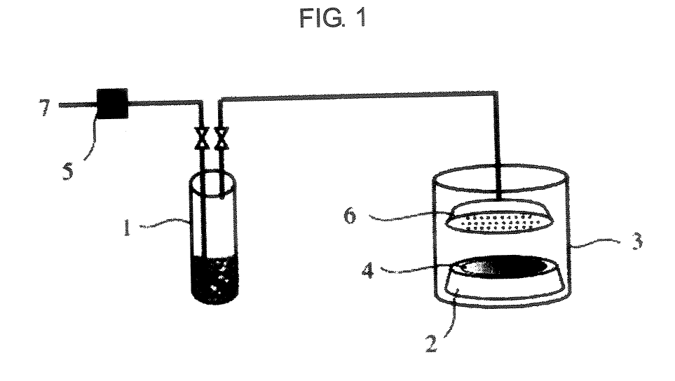

FIG. 1 is a schematic view of the CVD device for performing the chemical vapor deposition process in accordance with the present invention. In FIG. 1, 1 is a raw material container, 2 is an electrode acting as a heater and for plasma discharging, 3 is a decomposition reactor, 4 is a Si substrate, 5 is a gas flow controller, 6 is an electrode acting as a gas blowing shower head and for plasma discharging, and 7 is an inert gas feeding path.

In this example, the CVD device of FIG. 1 was employed and the film consisting of Si, O, C, and H was formed on the Si substrate 4.

That is, the dicyclopentyldimethoxysilane [(C—C₅H₉)₂Si(OCH₃)₂] was housed in the container 1. And, carrier gas (inert gas: He) was fed at a rate of 110 ml/min. Additionally, the inside of the container 1 was kept at 20 to 100° C.

The (c-C₅H₉)₂Si(OCH₃)₂ evaporated by bubbling of the carrier gas was led within the decomposition reactor 3. Originally, the inside of the decomposition reactor 3 was exhausted at a pressure of 3.5 Torr. Additionally, a pressure of the (c-C₅H₉)₂Si(OCH₃)₂ and the inert gas in the decomposition reactor 3 becomes 80 Torr and 245 Torr by feeding the raw material gas, respectively.

The Si substrate 4, which was kept on the electrode 2 acting as a heater and for plasma discharging, was heated at 200 to 500° C.

The distance between the electrode 2 acting as a heater and for plasma discharging, and the electrode 6 acting as a gas blowing shower head and for plasma discharging was set so that it was is 100 mm. And, a predetermined voltage was applied between the electrodes, and a plasma discharge of 200 W was generated.

And, the (c-C₅H₉)₂Si(OCH₃)₂ was decomposed, combined, and oxidized, and the film was formed on the Si substrate 4.

This film was investigated by XPS (X-ray photoelectron spectroscopy). The result demonstrated that the film included Si, O, and C as a constituent element. (Additionally, H is undetectable by the XPS).

Further, a current-voltage characteristic of this film was measured. The result demonstrated that a leak current at 20V was 1.0×10⁻⁸ A/cm² or less. That is, it is excellent as an insulating film.

In addition hereto, a capacity-voltage characteristic of the film was investigated, and the dielectric constant thereof was calculated from a film thickness and the electrode. The result was that the dielectric constant of the film was 2.1.

In addition hereto, the mechanical strength of the film was investigated with a nano-indentation method. The result was that the elastic modulus of the film was 8.3 GPa.

### A Comparative Example 1

The comparative example 1 was similar to the example 1 except that (CH₃)₂Si(OCH₃)₂ was employed instead of the (c-C₅H₉)₂Si(OCH₃)₂.

The dielectric constant of the film obtained in this comparative example 1 was 2.7. Further, the elastic modulus was 3 GPa. Thus, the comparative example 1 cannot acquire the characteristics of the present invention after all.

### A Comparative Example 2

The comparative example 2 was similar to the example 1 except that (C₂H₅)₂Si(OCH₃)₂ was employed instead of the (c-C₅H₉)₂Si(OCH₃)₂.

The dielectric constant of the film obtained in this comparative example 2 was 2.6. Further, the elastic modulus was 4 GPa. Thus, the comparative example 2 cannot acquire the characteristics of the present invention after all.

### A Comparative Example 3

The comparative example 3 was similar to the example 1 except that (C₆H₅)₂Si(OCH₃)₂ was employed instead of the (c-C₅H₉)₂Si(OCH₃)₂.

The dielectric constant of the film obtained in this comparative example 3 was 3.6. Further, the elastic modulus was 2 GPa. Thus, the comparative example 3 cannot acquire the characteristics of the present invention after all.

### A Comparative Example 4

The comparative example 4 was similar to the example 1 except that (c-C₆H₁₁)Si(OCH₃)₃ was employed instead of the (c-C₅H₉)₂Si(OCH₃)₂.

The dielectric constant of the film obtained in this comparative example 4 was 3.2. Further, the elastic modulus was 4 GPa. Thus, the comparative example 4 cannot acquire the characteristics of the present invention after all.

### A Comparative Example 5

The comparative example 5 was similar to the example 1 except that (n-C₅H₁₁)Si(OCH₃)₃ was employed instead of the (c-C₅H₉)₂Si(OCH₃)₂.

The dielectric constant of the film obtained in this comparative example 5 was 3.3. Further, the elastic modulus was 4 GPa. Thus, the comparative example 5 cannot acquire the characteristics of the present invention after all.

### A Comparative Example 6

The comparative example 6 was similar to the example 1 except that (c-C₅H₉)₃Si(OCH₃) was employed instead of the (c-C₅H₉)₂Si(OCH₃)₂.

It was impossible in this comparative example 6 to fabricate the uniform film to a degree at which the electrical measurement was possible. Thus, the comparative example 6 cannot acquire the characteristics of the present invention after all.

### A Comparative Example 7

The comparative example 7 was similar to the example 1 except that (c-C₅H₉)Si(OCH₃)₃ was employed instead of the (c-C₅H₉)₂Si(OCH₃)₂.

The dielectric constant of the film obtained in this comparative example 7 was 2.8. Further, the elastic modulus was 3 GPa. Thus, the comparative example 7 cannot acquire the characteristics of the present invention after all.

### AN EXAMPLE 2

The example 2 was performed according to the example 1, and the insulating film of which the dielectric constant was 2.20 was formed. And, the ultra violent rays of 4.7 mW/cm² (output power) was radiated to this film.

As a result, the dielectric constant decreased in proportion to the radiation time. And, the dielectric constant showed a minimum value with the radiation time of approx. 90 sec or so (a decrease by approx. 15% as compared with the value before the radiation). Additionally, when the ultra violent rays continued to be radiated, the dielectric constant became large gradually, so the radiation time was desirably approx. 130 sec or less.

### AN EXAMPLE 3

The example 3 was performed according to the example 1, and the insulating film of which the dielectric constant was 2.20 was formed. And, this film was heated for 30 minutes.

As a result, the dielectric constant decreased as the heating temperature rose. Its result is shown below.

TABLE

| Heating | Heating | Dielectric |
|---|---|---|
| temperature | time | constant |
| 300° C. | 30 minutes | 2.18 |
| 350° C. | 30 minutes | 2.14 |
| 400° C. | 30 minutes | 1.89 |
| 450° C. | 30 minutes | 1.84 |

### [How the Invention is Capable Industrial Exploitation]

The insulating film of which the dielectric constant is small and yet is excellent in the film strength is obtained. Thus, in particular, it is serviceably employed in the semiconductor field.

1. A film forming material, which is a material for forming a film with a chemical vapor deposition process, characterized in including dicyclopentyldimethoxysilane (c-C₅H₉)₂Si(OCH₃)₂.

2. The film forming material as claimed in claim 1, characterized in that said film forming material is a material for forming an insulating film of which a dielectric constant is 2.2 or less.

3. The film forming material as claimed in claim 1, characterized in that said film forming material is a material for forming an insulating film of which an elastic modulus is 5 GPa or more.

4. The film forming material as claimed in claim 1, characterized in that said film forming material is a material for forming a Si—O—C—H film.

5. A film forming method, which is a method of forming a film on a substrate with a chemical vapor deposition process, is characterized in comprising:
a feeding step of feeding dicyclopentyldimethoxysilane (c-C₅H₉)₂Si(OCH₃)₂; and
a deposition step of causing any decomposition product resulting from decomposition of the (c-C₅H₉)₂Si(OCH₃)₂ fed in said feeding step to deposit on said substrate.

6. The film forming method as claimed in claim 5, characterized in that the (c-C₅H₉)₂Si(OCH₃)₂ is fed by bubbling of inert gas.

7. The film forming method as claimed in claim 6, characterized in that a flow amount of the inert gas is 10 to 500 sccm.

8. The film forming method as claimed in claim 6, characterized in that with a feed ratio (pressure ratio) of the (c-C₅H₉)₂Si(OCH₃)₂ and the inert gas, the former/the latter is 1/10 to ½.

9. The film forming method as claimed in claim 6, characterized in that a total feed amount (a total pressure in a decomposition chamber) of the (C—C₅H₉)₂Si(OCH₃)₂ and the inert gas is 0.1 to 10 Torr.

10. The film forming method as claimed in claim 5, characterized in that the decomposition/deposition of the (c-C₅H₉)₂Si(OCH₃)₂ is carried out by using both of a plasma means and a heating means.

11. The film forming method as claimed in claim 5, characterized in that the decomposition/deposition of the (c-C₅H₉)₂Si(OCH₃)₂ is carried out by employing a plasma means including parallel plate electrodes of which an inter-electrode distance is 20 to 250 mm.

12. The film forming method as claimed in claim 5, characterized in that the decomposition/deposition of the (c-C₅H₉)₂Si(OCH₃)₂ is carried out by employing a plasma means in which one electrode of parallel plate electrodes acts as a substrate stage as well, and the other electrode acts as a blowing shower of the (c-C₅H₉)₂Si(OCH₃)₂ as well.

13. The film forming method as claimed in claim 5, characterized in further comprising an electromagnetic wave radiation step of radiating an electromagnetic wave to the film formed in the deposition step.

14. The film forming method as claimed in claim 5, characterized in further comprising a heating step of heating the film formed in the deposition step.

15. The film forming method as claimed in claim 13, characterized in that the electromagnetic wave being radiated is ultra violent rays, its output power is 1 to 10 mW/cm², and a radiation time is 0.1 to 130 sec.

16. The film forming method as claimed in claim 14, characterized in that a heating temperature is 300 to 500° C., and a heating time is one sec to one hour.
